(19) United States
(12) Patent Application Publication
(10) Pub. No.: US 2014/0024138 A1
(43) Pub. Date: Jan. 23, 2014

(54) METHOD FOR ETCHING METAL LAYER AND METHOD FOR MANUFACTURING A SEMICONDUCTOR DEVICE USING THE SAME

(71) Applicants: Hyungjoon Kwon, Seongnam-si (KR); Ken Tokashiki, Seongnam-si (KR); Jongchul Park, Seongnam-si (KR)

(72) Inventors: Hyungjoon Kwon, Seongnam-si (KR); Ken Tokashiki, Seongnam-si (KR); Jongchul Park, Seongnam-si (KR)

(21) Appl. No.: 13/941,071

(22) Filed: Jul. 12, 2013

(30) Foreign Application Priority Data
Jul. 20, 2012 (KR) 10-2012-0079368

(51) Int. Cl. H01L 21/3065; H01L 43/12

(52) U.S. Cl. CPC H01L 21/3065; H01L 43/12
USPC 438/3; 438/712

(57) ABSTRACT

The inventive concepts disclosed herein include, for instance, methods for etching a metal layer and methods for manufacturing a semiconductor device using the etched metal layer. A wafer including a metal layer and a mask layer on the metal layer may be loaded into a process chamber. An etching gas may be supplied into the process chamber to etch the metal layer exposed by the mask layer. After the etching process, the mask layer may be removed. The etching gas can include phosphorus (P) and fluorine (F). An RF power may be constantly or selectively supplied to the process chamber, or different levels of RF power can be selectively supplied. An etching gas can be supplied to the process chamber when the RF power is off or at a lower level. A surface activation gas can be supplied when the RF power is on or at a higher level.

### CROSS-REFERENCE TO RELATED APPLICATIONS

This U.S. non-provisional patent application claims priority under 35 U.S.C. §119 to Korean Patent Application No. 10-2012-0079368, filed on Jul. 20, 2012, the entirety of which is incorporated by reference herein.

### BACKGROUND

The inventive concepts described herein relate to methods for etching a metal layer and methods for manufacturing a semiconductor device using the etched metal layer.

Semiconductor devices are widely used in the electronics industry because of their small size, multi-function capabilities and low manufacturing costs. Data storage semiconductor devices can be used to store logic data. As technology has developed, data storage devices have become more highly integrated. Thus, widths of and spaces between elements constituting a data storage device have been reduced.

In addition to increased integration, high reliability of the data storage devices has been demanded. However, as integration density increases, it becomes more difficult to ensure the reliability of the data storage devices. Thus, research is being conducted to improve the reliability of highly integrated data storage devices.

### SUMMARY

Embodiments of the inventive concepts may provide methods for manufacturing a semiconductor device capable of effectively etching a metal layer.

In one aspect, a method for etching a metal layer may include loading a wafer including a metal layer and a mask layer on the metal layer into a process chamber. An etching gas may be supplied into the process chamber to etch the metal layer exposed by the mask layer, and the mask layer may be removed. The etching gas can include phosphorus (P) and fluorine (F).

In one embodiment, the etching gas can include PF₃.

In another embodiment, the method may further include exhausting a gas disposed in the process chamber. The exhausted gas may include a metal-PF₃ compound, and a weight ratio of the metal-PF₃ compound in the exhausted gas may be about 3 wt % to about 10 wt %.

In yet another embodiment, supplying the etching gas into the process chamber to etch the metal layer may further include applying a RF power into the process chamber to convert at least a portion of the etching gas into a plasma state.

In a still further embodiment, applying the RF power into the process chamber may further include alternately and repeatedly applying a first power and a second power smaller than the first power.

In another embodiment, the etching gas may be intermittently supplied between times when the first power is applied.

The method may further include supplying a surface activation gas into the process chamber. The surface activation gas may be supplied when the first power is applied.

The metal layer may include at least one of cobalt (Co), platinum (Pt), palladium (Pd), magnesium (Mg), iron (Fe), iridium (Ir), rhodium (Rh), or any alloy thereof.

A temperature of the wafer may be about 50 degrees Celsius to about 150 degrees Celsius when the metal layer is etched.

According to another aspect, a method for manufacturing a semiconductor device may include forming a magnetic structure on a substrate and forming a mask layer on the magnetic structure. The magnetic structure exposed by the mask layer can be etched to form a magnetic tunnel junction. At least a portion of the magnetic structure may be etched by an etching gas including phosphorus (P) and fluorine (F).

In one embodiment, etching the magnetic structure may include converting at least a portion of the etching gas into a plasma state.

Etching the magnetic structure may be performed in a process chamber. In one embodiment, the method may further include exhausting a gas disposed in the process chamber. The exhausted gas may include a metal-PF₃ compound, and a weight ratio of the metal-PF₃ compound in the exhausted gas may, for instance, be about 3 wt % to about 10 wt %.

The magnetic structure may include a first layer including at least one of cobalt (Co), platinum (Pt), palladium (Pd), magnesium (Mg), iron (Fe), iridium (Ir), rhodium (Rh), or any alloy thereof. The first layer may be etched by the etching gas including phosphorus (P) and fluorine (F).

In another embodiment, the magnetic structure may further include a second layer not including cobalt (Co), platinum (Pt), palladium (Pd), magnesium (Mg), iron (Fe), iridium (Ir), rhodium (Rh), and any alloy thereof. The second layer may be etched by a different material from the etching gas including phosphorus (P) and fluorine (F).

### BRIEF DESCRIPTION OF THE DRAWINGS

The inventive concepts will become more apparent in view of the attached drawings and the accompanying detailed description.

FIG. 1 is a cross-sectional view illustrating an etching apparatus for performing an etching process according to some embodiments of the inventive concepts;

FIG. 2 is a process flowchart of an etching process according to some embodiments of the inventive concepts;

FIGS. 3 and 4 are cross-sectional views of a wafer illustrating an etching process according to some embodiments of the inventive concepts;

FIGS. 5 to 8 are timing diagrams of an etching process according to various embodiments of the inventive concepts;

FIG. 9 is a cross-sectional view of a memory structure used to further illustrate a method for manufacturing a semiconductor device according to some embodiments of the inventive concepts;

FIG. 10 is a cross-sectional view of a memory structure used to further illustrate a method for manufacturing a semiconductor device according to other embodiments of the inventive concepts;

FIG. 11 a schematic block diagram illustrating an example of a memory system including semiconductor devices formed according to embodiments of the inventive concepts;

FIG. 12 a schematic block diagram illustrating an example of a memory card including semiconductor devices formed according to embodiments of the inventive concepts; and

FIG. 13 a schematic block diagram illustrating an example of information processing systems including semiconductor devices formed according to embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and assist those skilled in the art in understanding the inventive concepts. In the drawings, embodiments of the inventive concepts are not limited to the specific examples provided herein and features thereof may be exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiments in the detailed description may be described using somewhat schematic sectional views as exemplary views of the inventive concepts. Shapes of the various features and elements shown in the exemplary views may be modified according to manufacturing techniques and/or allowable errors. Therefore, the embodiments of the inventive concepts are not limited to the specific shapes illustrated in the exemplary views, but may include other shapes that may be created according to desired manufacturing processes, for instance. Areas exemplified in the drawings may have additional general properties which are used to illustrate specific shapes of elements in the various embodiments. This, however, should not be construed as limiting to the scope of the inventive concepts.

It will be also understood that although the terms first, second, third, etc., may be used herein to describe various elements, but these elements should not be limited by these terms. Rather, these terms are only used to distinguish one element from another element. Thus, a first element in some embodiments could be termed a second, third, etc., element in other embodiments (and vice versa) without departing from the teachings of the present inventive concepts. Exemplary embodiments of aspects of the present inventive concepts explained and illustrated herein include their complementary counterparts. The same reference numerals or the same reference designators denote the same elements throughout the specification.

Moreover, exemplary embodiments may be described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, neither the exemplary embodiments nor the inventive concepts should not be construed as being limited to the specific shapes of regions illustrated herein, but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of the inventive concepts.

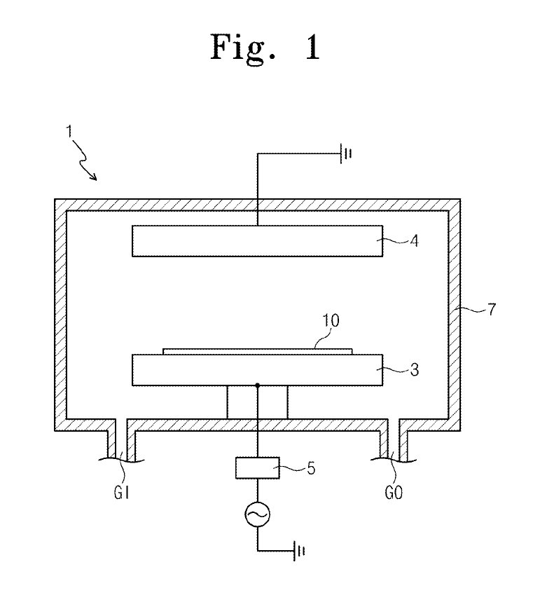

FIG. 1 is a cross-sectional view illustrating an etching apparatus 1 for performing an etching process according to various embodiments of the inventive concepts. Referring to FIG. 1, an etching apparatus 1 may include a process chamber 7 into which a wafer 10 can be loaded. The etching apparatus may include a lower electrode 3 and an upper electrode 4 facing each other. The lower electrode 3 may be connected to a source power 5 for applying a radio frequency (RF) power. The upper electrode 4 may be grounded or be applied with a RF power having a frequency band different from that of the RF power applied to the lower electrode 3.

In another embodiment, the upper electrode 4 may be applied with a RF power corresponding to a source power for generating plasma, and the lower electrode 3 may be applied with a RF power corresponding to a bias power for controlling energy of ions colliding with the wafer 10.

The etching apparatus may further include a gas inflow path GI for supplying an etching gas into the process chamber 7 and a gas outflow path GO for exhausting a reacting gas after the etching process. The elements and the arrangement of elements in the etching apparatus 1 are not limited to the embodiment illustrated, however, and may be modified without departing from the inventive principles.

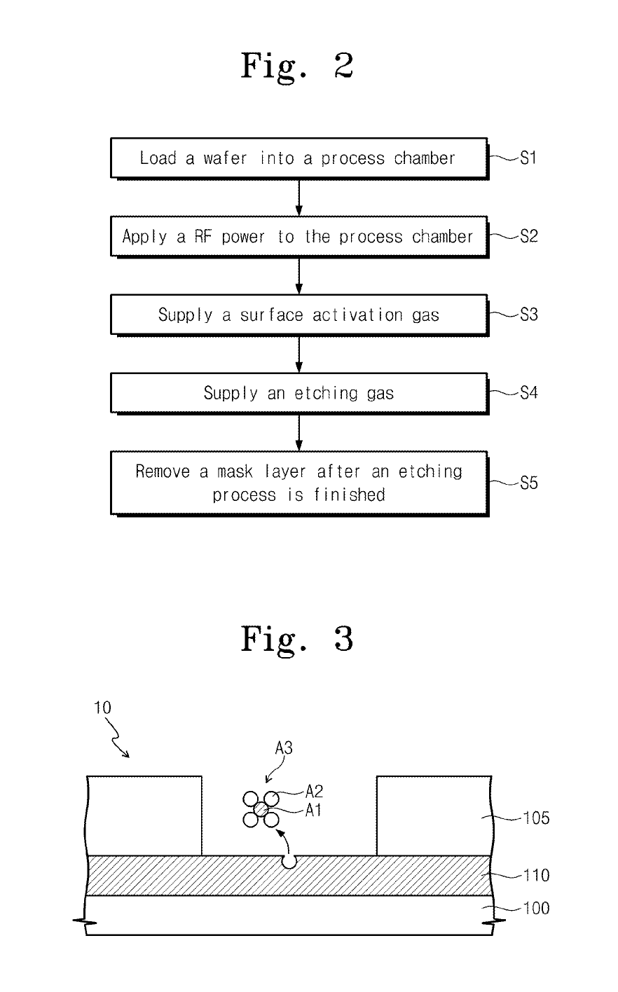

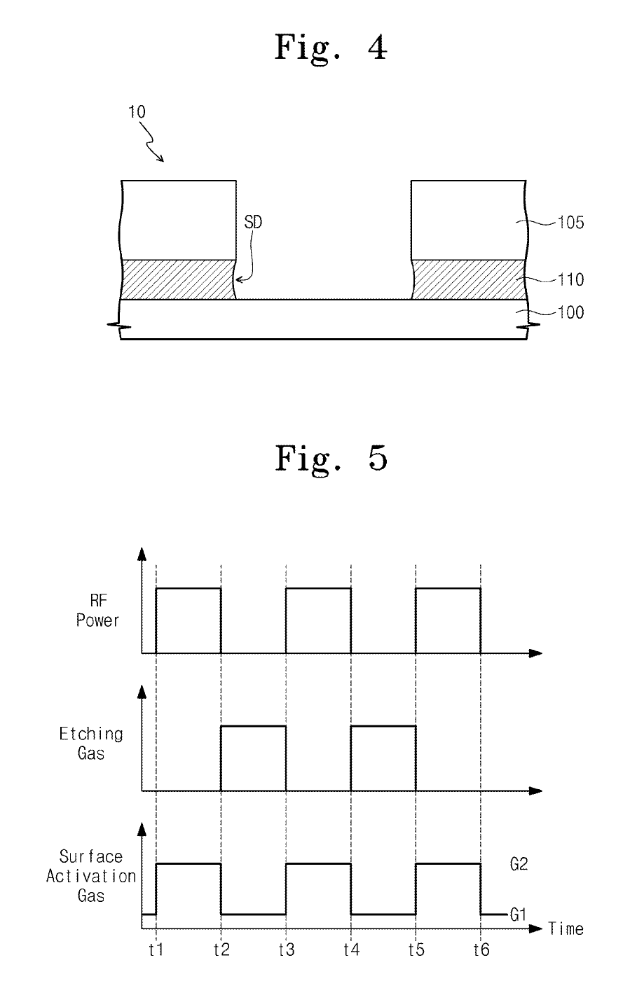

FIG. 2 is a process flowchart illustrating an etching process according to various embodiments of the inventive concepts. FIGS. 3 and 4 are schematic cross-sectional views of a wafer which help to illustrate an etching process according to principles of the inventive concepts.

Referring to FIGS. 1 to 4, an etching process according to principles of the inventive concepts will now be described. During a first step (S1), the wafer 10 can be loaded into the process chamber 7. The wafer 10 may include a substrate 100 and a metal layer 110 on the substrate 100. The substrate 100 may have a semiconductor based structure such as silicon, silicon on insulator (SOD, silicon-germanium (SiGe), germanium (Ge), or gallium-arsenic (GaAs). The metal layer 110 may include at least one of cobalt (Co), platinum (Pt), palladium (Pd), magnesium (Mg), iron (Fe), iridium (Ir), rhodium (Rh), or any alloy thereof. A mask layer 105 may be provided on the metal layer 110. The mask layer 105 may, for example, include photoresist and/or silicon nitride.

After the wafer 10 is loaded into the process chamber 7, RF power can be applied to the process chamber 7 during a second step (S2). In one embodiment, the RF power may be applied at a frequency of about 13 MHz to about 100 MHz. A surface activation gas may then be injected into the process chamber 7 during a third step (S3). The surface activation gas may reduce a bond energy between atoms of a surface of the metal layer 110 exposed by the mask layer 105, so that an etching gas may more easily react with the metal layer 110. For example, the surface activation gas may include at least one of H₂, NH₃, CO, CO₂, He, Ne, Ar, Kr, Xe, N₂, or O₂.

An etching gas may then be injected into the process chamber 7 during a fourth step (S4). The etching gas may, for instance, include phosphorus (P) and fluorine (F). For example, the etching gas may include phosphorus tri-fluoride (PF₃).

At least a portion of the etching gas may be converted into a plasma state using the RF power supplied by the power source 5. For example, if the etching gas includes PF₃ gas, the PF₃ gas may be converted into a plasma gas including a PF₃ radical (PF₃*), a PF₂ radical (PF₂*), a P radical (P*), and/or an F radical (F*). The amount of PF₃ radicals (PF₃*) may be greater than those of other radicals. For example, the amount of PF₃ radicals (PF₃*) may be equal to or greater than about 40% of the total amount of radicals generated from the PF₃ gas. A metal-PF₃ compound is more volatile than other compounds formed by reaction of the metal in the metal layer 110 and other radicals. Although the metal-PF₃ compound may be re-dissociated into the metal and PF₃ in the plasma, a re-dissociation rate of the metal-PF₃ compound is lower than those of the other compounds.

As illustrated in FIG. 3, the PF₃ radical (PF₃*) A2 may react with a metal atom A1 to form the metal-PF₃ compound A3. For example, the metal-PF₃ compound A3 may include Pt(PF₃)4, Pd(PF₃)4, Ir(PF₃)4, Rh(PF₃)4, Co(PF₃)4, Mg(PF₃)4, or Fe(PF₃)4. The process chamber gases may then be exhausted through the gas outflow path GO. The exhausted gas may therefore include the metal-PF₃ compound. A weight ratio of the metal-PF₃ compound may, for example, be between about 3 wt % to about 10 wt % of the exhausted gas.

In a conventional etching process, a typical etching gas may react with one of cobalt (Co), platinum (Pt), palladium (Pd), magnesium (Mg), iron (Fe), iridium (Ir), and rhodium (Rh), thereby forming a reactant compound (hereinafter, referred to as a “reactant”). In such a case, the reactant may have a lower saturated vapor pressure than a compound formed by reaction of the general etching gas and one of other metals, silicon, and/or silicon oxide. Thus, reacting speeds of cobalt (Co), platinum (Pt), palladium (Pd), magnesium (Mg), iron (Fe), iridium (Ir), and rhodium (Rh) may be slower than those of other metals, silicon, and/or silicon oxide, and a re-depositing rate of the reactant on the exposed surface may therefore be significant. As a result, a sidewall profile of an etching target may become sloped by the reactant, or an interlayer electrical short may occur due to the re-deposited reactant.

According to principles of the present inventive concepts, however, the compounds formed by reacting with the metal have great volatility in the etching process, such that the etching process has characteristics similar to that of a chemical etching process. Thus, as illustrated in FIG. 4, a sidewall SD of the metal layer 110 after the etching process according to these principles may be laterally recessed from a sidewall of the mask layer 105. Additionally, since the re-dissociation rate of the etch-reactant is low in the plasma, it is possible to substantially prevent slope etching of the sidewall SD as well as interlayer electrical shorts.

The etching process according to some embodiments of the inventive concept may be performed at a low temperature. For example, a temperature of the wafer 10 may be between about 50 degrees Celsius to about 150 degrees Celsius during the etching process. Thus, it is also possible to substantially prevent elements of a semiconductor device formed on the wafer 10 from being deteriorated due to high temperatures of the process chamber before the etching process. A pressure in the process chamber 7 may be between about 0.1 Torr to about 1 Torr during the etching process.

After the etching process is finished, the mask layer 105 may be removed during a fifth step (S5). The mask layer 105 may be removed, for example, by an ashing process. In another embodiment, the mask layer 105 may be removed using a wet cleaning process. The wet cleaning process may, for instance, include a SPM treating process and/or an APM treating process performed on the wafer 10. The SPM treating process may, for example, be performed using a mixture solution of sulfuric acid and hydrogen peroxide. A ratio of sulfuric acid to hydrogen peroxide may be between about 1:1 to about 1:4. The APM treating process may be performed, for example, using a mixture solution of ammonium hydroxide, hydrogen peroxide, and water. A ratio between ammonium hydroxide, hydrogen peroxide, and water may, for instance, be between about 1:1:5 to about 0.05:1:5.

FIGS. 5 to 8 are timing diagrams illustrating the timing of various steps in an etching process according to various embodiments of the inventive concepts. These various embodiments will now be described in additional detail with additional reference to FIGS. 5-8.

As illustrated in FIG. 5, the RF power applied to the process chamber 1 during the etching process may be repeatedly turned-on and turned-off. An RF power during the on-state may, for instance, be between about 160 W to about 240 W. As further shown in FIG. 5, the etching gas may be supplied into the process chamber 1 during the off-states (e.g., between the on-states). In other words, the steps of applying the RF power and supplying the etching gas may be alternately and repeatedly performed during the etching process. By supplying the etching gas during the RF power off-times, the re-dissociation rate of the reactant of the metal and the etching gas may be further reduced. A flow rate of the etching gas may, for example, be between about 3 scm (standard cubic meter)/min to about 10 scm/min.

A flow rate of the supply of the surface activation gas may be controlled to correspond with the supply of the RF power. For instance, a supply amount G2 of the surface activation gas during the RF power on-state may be greater than a supply amount G1 of the surface activation gas during the RF power off-state. In one embodiment, for example, the second supply rate G2 of the surface activation gas during the on-state may be between about 80 scm to about 120 scm, while the first supply amount G1 of the surface activation gas during the off-state may be between about 10 scm to about 50 scm.

Cycles of applying the RF power and supplying the etching gas may be repeatedly performed with a period of between about 100 msec to about 1000 msec. For example, a time between t1 and t2 may be between about 50 msec to about 500 msec, and a time between t1 and t3 may be between about 100 msec to about 1000 msec.

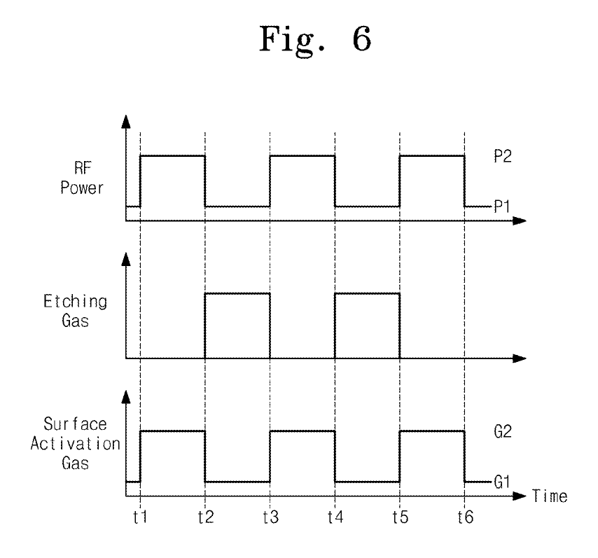

FIG. 6 illustrates another embodiment incorporating principles of the present inventive concepts. As illustrated in FIG. 6, a first RF power P1 and a second RF power P2 may be alternately and repeated applied. The first RF power P1 may be smaller than the second RF power P2. The second RF power P2 may, for example, be between about 160 W to about 240 W, and the first RF power P1 may be between about 20 W to about 100 W. The etching gas may be intermittently supplied between times during which the second power P2 is applied (i.e., the etching gas may be supplied while the first power P1 is being applied).

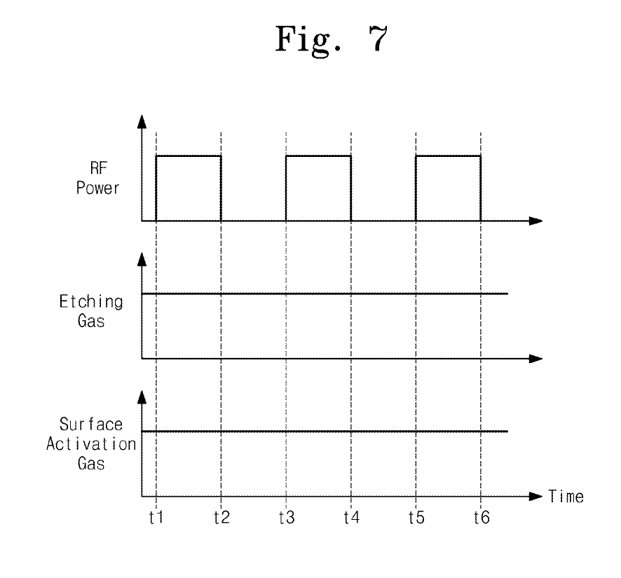

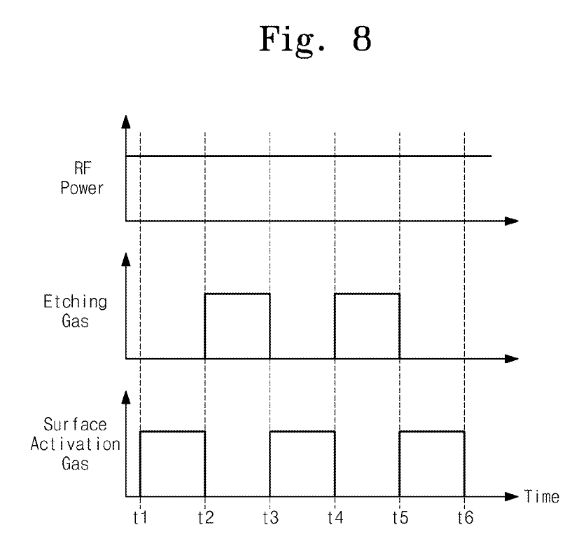

FIG. 7 illustrates yet another embodiment incorporating principles of the present inventive concepts. As illustrated in FIG. 7, the RF power may be repeatedly turned-on and turned-off, while the etching gas and the surface activation gas are continuously supplied. Alternatively, in yet another embodiment, as illustrated in FIG. 8, the etching gas and the surface activation gas may be alternately supplied, and the RF power may be continuously applied.

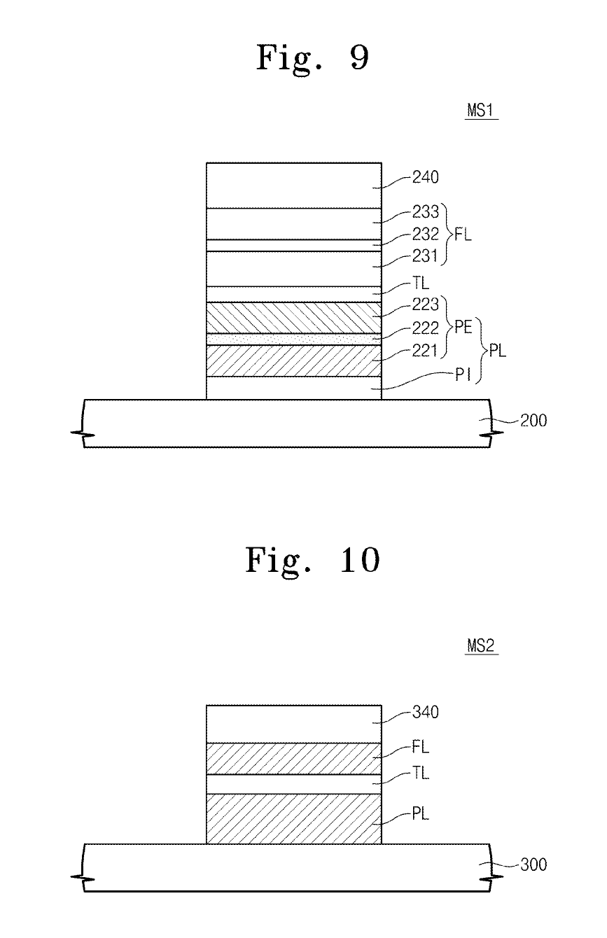

FIG. 9 is a cross-sectional view of a memory structure MS1 which can be used for illustrating a method for manufacturing a semiconductor device according to various embodiments of the present inventive concepts. Referring to FIG. 9, a semiconductor device constructed according to some embodiments of the present inventive concepts may include a magnetic tunnel junction (MTJ). For example, the semiconductor device may be a horizontally-orientated magnetic memory device in which magnetization directions of magnetic layers are substantially parallel to a top surface of a tunnel barrier layer disposed between the magnetic layers.

As shown in FIG. 9, a magnetic structure MS1 may be formed on a substrate 200. The magnetic structure MS 1 may include a reference layer PL, a tunnel barrier layer TL, and a free layer FL which are sequentially stacked on the substrate 200. The substrate 200 may, for example, comprise a semiconductor based structure such as silicon, silicon on insulator (SOI), silicon-germanium (SiGe), germanium (Ge), or gallium-arsenic (GaAs). The substrate 200 may be a substrate doped with dopants of a first conductivity type. For example, the substrate 200 may be a p-type silicon substrate lightly doped with p-type dopants. The reference layer PL may include a pinning layer PI and a pinned layer PE on the pinning layer PI. The pinning layer PI may include an anti-ferromagnetic material. For example, the pinning layer PI may include at least one of PtMn, IrMn, MnO, MnS, MnTe, MnF₂, FeCl₂, FeO, CoCl₂, CoO, NiCl₂, NiO, and/or Cr. In an embodiment, the pinning layer PI may include one or more precious metals. The precious metals may include at least one of ruthenium (Ru), rhodium (Rh), palladium (Pd), osmium (Os), iridium (Ir), platinum (Pt), gold (Au), and/or silver (Ag).

The pinned layer PE may have a magnetization direction fixed by the pinning layer PI. The pinned layer PE may include first magnetic layers 221 and 223 and a first non-magnetic layer 222. The first non-magnetic layer 222 may be disposed between the first magnetic layers 221 and 223. Magnetization directions of the first magnetic layers 221 and 223 may be fixed anti-parallel to each other. The first magnetic layers 221 and 223 may include a ferromagnetic material. For example, the first magnetic layers 221 and 223 may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂. The first non-magnetic layer 222 may include a precious metal. For example, the first non-magnetic layer 222 may include at least one of ruthenium (Ru), iridium (Ir), and/or rhodium (Rh).

The tunnel barrier layer TL may include a non-magnetic insulating material. For example, the tunnel barrier layer TL may include at least one of magnesium oxide, titanium oxide, aluminum oxide, magnesium-zinc oxide, or magnesium-boron oxide. The free layer FL may include a material having a changeable magnetization direction. The free layer FL may include second magnetic layers 231 and 233 and a second non-magnetic layer 232. The second non-magnetic layer 232 may be disposed between the second magnetic layers 231 and 233. The second magnetic layers may include a ferromagnetic material. For example, the second magnetic layers 231 and 233 may include at least one of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂. The second non-magnetic layer 232 may include at least one of ruthenium (Ru), iridium (Ir), and/or rhodium (Rh).

The free layer FL and the reference layer PL may be formed by a sputtering process or a plasma enhanced-chemical vapor deposition (PE-CVD) process. A mask layer 240 may be formed on the free layer FL. The mask layer 240 may include photoresist and/or silicon nitride.

The magnetic structure MS1 may be patterned using the mask layer 240 as an etch mask, thereby forming a magnetic tunnel junction (MTJ). At least a portion of the layers constituting the magnetic structure MS1 may be patterned using one or more of the etching processes (hereinafter, referred to as ‘a first etching process’) described previously with reference to FIGS. 1 to 8.

For example, the magnetic structures MS1 may include first layers including cobalt (Co), platinum (Pt), palladium (Pd), magnesium (Mg), iron (Fe), iridium (Ir), rhodium (Rh), or any alloy thereof, and second layers not including cobalt (Co), platinum (Pt), palladium (Pd), magnesium (Mg), iron (Fe), iridium (Ir), rhodium (Rh), and any alloy thereof. The first layers may be patterned using the first etching process, and the second layers may be patterned using a second etching process different from the first etching process.

In one embodiment, the second etching process may be an etching process using at least one material other than PF₃ as an etching gas. For example, the second etching process may use an etching gas including SF₆, NF₃, Cl₂, CH₃OH, CH₄, CO, NH₃, and/or Ar. A portion of the reference layer PL may be patterned using the first etching process, and the remaining layers of the magnetic structure MS1 may be patterned using the second etching process.

FIG. 10 is a cross-sectional view of a magnetic structure MS2 used to illustrate a method of manufacturing a semiconductor device according to other embodiments incorporating the inventive concepts. In one embodiment, a semiconductor device may be a perpendicular magnetic memory device in which magnetization directions of magnetic layers are oriented substantially perpendicular to a top surface of a tunnel barrier layer between the magnetic layers. For simplicity, descriptions with respect to the same elements as in the aforementioned embodiment will be omitted or mentioned only briefly.

Referring to FIG. 10, a magnetic structure MS2 may be disposed on a substrate 300. The magnetic structure MS2 may include a reference layer PL, a tunnel barrier layer TL, and a free layer FL which are sequentially stacked on the substrate 300. The reference layer PL may have a magnetization direction fixed in one direction, and the free layer FL may have a magnetization direction changeable between a direction parallel to or a direction anti-parallel to the fixed magnetization direction of the reference layer PL. The magnetization directions of the free layer FL and the reference layer PL may be substantially perpendicular to a top surface of the tunnel barrier layer TL.

For example, each of the reference layer PL and the free layer FL may include at least one of a perpendicular magnetic material (e.g., CoFeTb, CoFeGd, and/or CoFeDy), a perpendicular magnetic material having an L1₀ structure, CoPt of a hexagonal close packed (HCP) lattice structure, and/or a stack structure. The perpendicular magnetic material having the L1₀ structure may include at least one of FePt having the L1₀ structure, FePd having the L1₀ structure, CoPd having the L1₀ structure, or CoPt having the L1₀ structure. The stack structure may include magnetic layers and non-magnetic layers which are alternately and repeatedly stacked. For example, the stack structure may include at least one of (Co/Pt)n, (CoFe/Pt)n, (CoFe/Pd)n, (Co/Pd)n, (Co/Ni)n, (CoNi/Pt)n, (CoCr/Pt)n, and/or (CoCr/Pd)n (where ‘n’ denotes a stacking number of the magnetic layer and the non-magnetic layer).

The reference layer PL may be thicker than the free layer FL, and/or a coercive force of the reference layer PL may be greater than that of the free layer FL. The tunnel bather layer TL may include at least one of magnesium oxide, titanium oxide, aluminum oxide, magnesium-zinc oxide, or magnesium-boron oxide.

In one embodiment, the magnetic structure MS2 may include first layers including at least one of cobalt (Co), platinum (Pt), palladium (Pd), magnesium (Mg), iron (Fe), iridium (Ir), rhodium (Rh), or any alloy thereof. The first layers of the magnetic structure MS2 may be patterned using the first etching process. The magnetic structure MS2 may further include second layers not including cobalt (Co), platinum (Pt), palladium (Pd), magnesium (Mg), iron (Fe), iridium (Ir), rhodium (Rh), and any alloy thereof. The second layers of the magnetic structure MS2 may be patterned using a second etching process, different from the first etching process.

For example, the second etching process may be an etching process using at least one material other than PF₃ as an etching gas. For example, the second etching process may use an etching gas including SF₆, NF₃, Cl₂, CH₃OH, CH₄, CO, NH₃, and/or Ar.

It should be noted that the elements of the aforementioned embodiments may be replaced by or combined with elements from the other embodiments without departing from the spirit and scope of the inventive concepts.

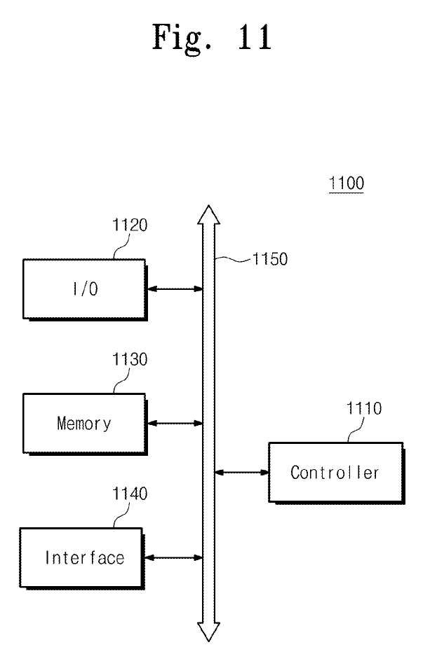

FIG. 11 is a schematic block diagram of a memory system illustrating one example of a system which can include semiconductor devices formed according to embodiments of the inventive concepts.

Referring to FIG. 11, an electronic system 1100 according to embodiments of the inventive concepts may include a controller 1110, an input/output (I/O) unit 1120, a memory device 1130, an interface unit 1140, and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted. The memory device 1130 may include at least one of the semiconductor devices constructed according to embodiments of the inventive concepts.

The controller 1110 may include at least one of a microprocessor, a digital signal processor, a microcontroller, and other logic devices. The other logic devices may have a similar function to any one of the microprocessor, the digital signal processor and the microcontroller. The I/O unit 1120 may include a keypad, a keyboard and/or a display unit. The memory device 1130 may store data and/or commands. The interface unit 1140 may transmit electrical data to a communication network or may receive electrical data from the communication network. The interface unit 1140 may operate wirelessly or via one or more wires or cables. For example, the interface unit 1140 may include an antenna for wireless communication or a transceiver for cable communication. Although not shown in the drawings, the electronic system 1100 may further include a fast DRAM device and/or a fast SRAM device which acts as a cache memory for improving an operation of the controller 1110.

The electronic system 1100 may be utilized for instance, in a personal digital assistant (PDA), a portable computer, a web tablet, a wireless phone, a mobile phone, a digital music player, a memory card or other electronic products. The other electronic products may also receive or transmit information data by wireless communication.

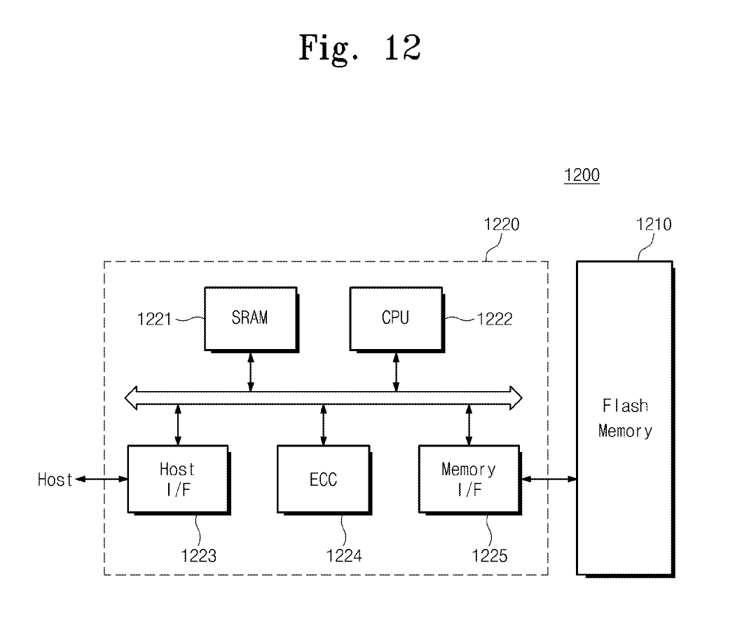

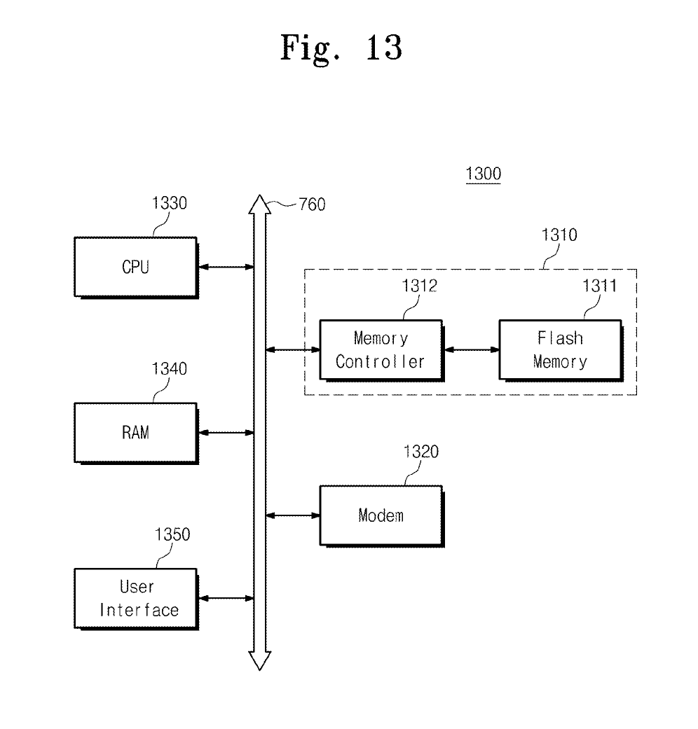

FIG. 12 a schematic block diagram of a memory card illustrating a memory card embodiment which could include one or more semiconductor devices formed according to embodiments of the inventive concept.

Referring to FIG. 12, a memory card 1200 may include a memory device 1210. The memory device 1210 may include at least one of the semiconductor devices constructed according to the aforementioned embodiments. The memory device 1210 may further include other types of semiconductor memory devices (e.g., a DRAM device and/or a SRAM device) which are different from the semiconductor devices constructed according to the embodiments described above. The memory card 1200 may include a memory controller 1220 that controls data communication between a host and the memory device 1210. The memory device 1210 and the memory controller 1220 may include a semiconductor device constructed according to principles of the inventive concepts.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210.

Although not shown in the drawings, the memory card 1200 may further include a read only memory (ROM) device that stores code data to interface with the host. The memory card 1200 may be used as a portable data storage card. Alternatively, the memory card 1200 may be implemented as a solid state disk (SSD) used as a hard disk for a computer system.

FIG. 13 a schematic block diagram of an information processing system 1300 which may include semiconductor devices formed according to principles of the inventive concepts.

Referring to FIG. 13, a flash memory system 1310 which includes one or more of the semiconductor devices constructed according to the principles of the present inventive concepts may be installed in an information processing system 1300 such as a mobile device or a desk top computer. The information processing system 1300 according to the inventive concepts may further include a modem 1320, a central processing unit (CPU) 1330, a random access memory (RAM) 1340, and a user interface unit 1350 that are electrically connected to the flash memory system 1310 through a system bus 1360. The flash memory system 1310 may be the same as the aforementioned memory card. Data processed by the CPU 1330 or data inputted from outside of the flash memory system 1310 may be stored in the flash memory system 1310.

The flash memory system 1310 may be a solid state disk (SSD) and the information processing system 1300 may stably store massive amounts of data in the flash memory system 1310. Additionally, since the reliability of the flash memory system 1310 is high, the flash memory system 1310 may reduce resources otherwise consumed for correcting errors. Thus, it is possible to realize an information processing system 1300 having a fast data exchange function. Even though not shown in the drawings, an application chipset and/or a camera image processor (CIS) used as an input/output unit may further be provided in the information processing system 1300.

The semiconductor devices described above may be encapsulated using various packaging techniques. For example, semiconductor devices constructed according to principles of the present inventive concepts may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi chip package (MCP) technique, a wafer-level fabricated package (WFP) technique, a wafer-level processed stack package (WSP) technique, or other technique as will be known to those skilled in the art.

According to the inventive concepts, it is possible to reduce the re-depositing rate of the etching reactant generated in the etching process of the metal layer. Thus, an etching process more suitable to fine patterns and therefore higher integration densities may be provided.

While the inventive concept has been described with reference to example embodiments, it will be apparent to those skilled in the art that various changes and modifications may be made thereto without departing from the spirit and scope of the inventive concepts. Therefore, it should be understood that the above embodiments are not limiting, but are illustrative only. Thus, the scope of the inventive concepts are to be determined by the broadest permissible interpretation of the following claims and their equivalents, and should not be restricted or limited by the foregoing description.

What is claimed is:

1. A method for etching a metal layer comprising:
loading a wafer into a process chamber, said wafer comprising a metal layer and a mask layer on the metal layer;
supplying an etching gas into the process chamber to etch the metal layer exposed by the mask layer; and
removing the mask layer,
wherein the etching gas includes phosphorus (P) and fluorine (F).

2. The method of claim 1, wherein the etching gas includes PF₃.

3. The method of claim 2, further comprising:
exhausting a gas from the process chamber,
wherein the exhausted gas includes a metal-PF₃ compound; and
wherein a weight ratio of the metal-PF₃ compound in the exhausted gas is approximately between about 3 wt % to about 10 wt %.

4. The method of claim 2, wherein supplying the etching gas into the process chamber to etch the metal layer comprises:
applying a RF power into the process chamber to convert at least a portion of the etching gas into a plasma state.

5. The method of claim 4, wherein applying the RF power comprises:
alternately applying a first power and a second power, wherein the second power is smaller than the first power.

6. The method of claim 5, wherein the etching gas is intermittently supplied between times during which the first power is applied.

7. The method of claim 5, further comprising:
supplying a surface activation gas into the process chamber,
wherein the surface activation gas is supplied when the first power is applied.

8. The method of claim 1, wherein the metal layer includes at least one of cobalt (Co), platinum (Pt), palladium (Pd), magnesium (Mg), iron (Fe), iridium (Ir), rhodium (Rh), or any alloy thereof.

9. The method of claim 1, wherein a temperature of the wafer is between about 50 degrees Celsius to about 150 degrees Celsius when the metal layer is etched.

10. A method for manufacturing a semiconductor device comprising:
forming a magnetic structure on a substrate;
forming a mask layer on the magnetic structure; and
etching the magnetic structure exposed by the mask layer to form a magnetic tunnel junction,
wherein at least a portion of the magnetic structure is etched using an etching gas including phosphorus (P) and fluorine (F).

11. The method of claim 10, wherein etching the magnetic structure comprises converting at least a portion of the etching gas into a plasma state.

12. The method of claim 10, wherein etching the magnetic structure is performed in a process chamber, the method, further comprising:
exhausting a gas from the process chamber,
wherein the exhausted gas includes a metal-PF₃ compound; and
wherein a weight ratio of the metal-PF₃ compound in the exhausted gas is approximately between about 3 wt % to about 10 wt % of the exhausted gas.

13. The method of claim 10, wherein the etching gas includes PF₃.

14. The method of claim 10, wherein the magnetic structure includes a first layer including at least one of cobalt (Co), platinum (Pt), palladium (Pd), magnesium (Mg), iron (Fe), iridium (Ir), rhodium (Rh), or any alloy thereof; and
wherein the first layer is etched by the etching gas including phosphorus (P) and fluorine (F).

15. The method of claim 14, wherein the magnetic structure further includes a second layer not including cobalt (Co), platinum (Pt), palladium (Pd), magnesium (Mg), iron (Fe), iridium (Ir), rhodium (Rh), and any alloy thereof; and
wherein the second layer is etched using a different material than the etching gas including phosphorus (P) and fluorine (F).

16. A method of etching a metal layer of a wafer in a process chamber, said method comprising:
supplying a surface activation gas to the process chamber during a time in which a first RF power level is applied to the process chamber, said surface activation gas selected to reduce a bond energy between atoms of a surface of the metal layer; and
supplying an etching gas to the process chamber during a time in which no RF power or a second, lower RF power level is applied to the process chamber,
wherein the etching gas comprises phosphorus (P) and fluorine (F).

17. A method according to claim 16, further comprising alternately supplying the first RF power level and no RF power or the second, lower RF power level to the process chamber.

18. A method according to claim 16, wherein the etching gas comprises phosphorus tri-flouride (PF₃), wherein the etching gas is exhausted from the process chamber, and wherein a weight ratio of a metal-PF₃ compound in the exhausted gas is approximately between 3 wt % to 10 wt % of the exhausted gas.

19. A method according to claim 16, wherein the first RF power level applied to the process chamber converts at least a portion of the etching gas into a plasma state.
